(19) United States
(12) Patent Application Publication
(10) Pub. No.: US 2013/0213171 A1
(43) Pub. Date: Aug. 22, 2013

(54) SUBSTRATE TRANSFER APPARATUS

(71) Applicant: Samsung Electronics Co., Ltd., (US)

(72) Inventors: Myung Nam KWAG, Suwon-si (KR); Jae Chul HWANG, Seoul (KR)

(73) Assignee: SAMSUNG ELECTRONICS CO., LTD., Suwon-Si (KR)

(21) Appl. No.: 13/771,437

(22) Filed: Feb. 20, 2013

(30) Foreign Application Priority Data
Feb. 21, 2012 (KR) 10-2012-0017602

(51) Int. Cl. H01L 21/677

(52) U.S. Cl. CPC H01L 21/67742
USPC 74/490.05; 901/27

(57) ABSTRACT

A substrate transfer apparatus has a plurality of arms which rotate on different shafts. A first driver rotates the first arm, a second driver rotates a second arm coupled to the first arm, a third driver rotates a third arm coupled to the second arm, and a fourth arm rotates with rotation of the third arm and is coupled to the third arm. The drivers control rotation of the arms to perform different operations in transferring the substrate between different processing locations.

### CROSS-REFERENCE TO RELATED APPLICATION

This application claims the benefit of Korean Patent Application No. 2012-0017602, filed on Feb. 21, 2012 in the Korean Intellectual Property Office, the disclosure of which is incorporated herein by reference in its entirety.

### BACKGROUND

1. Field

The present disclosure relates to semiconductor manufacturing.

2. Description of the Related Art

A semiconductor device is made by forming circuit patterns on different regions or levels of a substrate. These patterns may be formed using various processes including a deposition process to form a thin film, an ion injection process, a thermal oxidation or a heat treatment process, a photo process and an etching process. In order to proceed with these processes, various types of manufacturing equipment are used along a semiconductor manufacturing line.

Semiconductor manufacturing equipment includes those which process semiconductor substrates in a unit of a single sheet and those which process semiconductor substrates in batches, e.g., in a unit of twenty five sheets.

In single-unit type equipment, a sputtering apparatus, a rapid heat treatment apparatus, an etching apparatus, an ashing apparatus, a coating apparatus, and an exposure apparatus may be included. In these or other processes, the substrates to be processed are held in a cassette unit. Thus, a process is needed to transfer the semiconductor substrates one-by-one from the cassette unit to a chamber inside the semiconductor manufacturing equipment.

Depending on the equipment, and even with batch-type equipment, a process of transferring a semiconductor substrate from an outside cassette to an inside cassette at an inside a chamber is performed.

Thus a substrate transfer apparatus is used to bring the substrates loaded in the cassette to inside a chamber or, reversely, to transfer the semiconductor substrates from an inside a chamber to an outside cassette.

### SUMMARY

In accordance with one or more embodiments, a substrate transfer apparatus is provided to increase transfer efficiency of a substrate during a semiconductor manufacturing process.

In these or additional embodiments, a substrate transfer apparatus is provided which has an extensive range of motion.

In accordance with one embodiment, a substrate transfer apparatus includes a first arm, a first driving unit, a second arm, a second driving unit, a third arm, a third driving unit, and a fourth arm. The first arm may be configured to rotate on a first rotating shaft. The first driving unit may be configured to rotate the first arm. The second arm may be configured to rotate on a second driving shaft disposed at the first arm. The second driving unit may be configured to rotate the second arm. The third arm may be configured to rotate on a third rotating shaft disposed at the second arm. The third driving unit may be configured to rotate the third arm. The fourth arm may be configured to rotate along with rotation of the third arm and to rotate on a fourth rotating shaft disposed at the third arm. The fourth arm may be configured to rotate by receiving a driving force of the third driving unit.

The substrate transfer apparatus may further include a power transmission unit configured to deliver a driving force of the third driving unit to the fourth arm. The power transmission unit may include a belt, and/or may include a first belt pulley configured to be rotated by the driving force of the third driving unit, and a second belt pulley configured to rotate the fourth arm. The belt may be mounted at the first belt pulley and the second belt pulley.

The substrate transfer apparatus may further include a hand mounted at the fourth arm so as to protrude from one side of the fourth arm, and configured such that a substrate is placed thereon.

The substrate transfer apparatus may perform a rotating operation, a forward/backward operation, and a mobile operation. The rotating operation may be configured to rotate on the first rotating shaft. The forward/backward operation may be configured to move the hand forward or backward. The mobile operation may be configured to move the hand in a direction perpendicular to the forward/backward operation on a horizontal plane.

The mobile operation may be provided as the firs arm, second arm, third arm, and fourth arm rotate. When the mobile operation is provided, the first arm and the third arm may rotate in a first direction, while the second arm and the fourth arm rotate in a second direction. The forward/backward operation may be provided as the second arm, the third arm, and the fourth arm rotate.

A length from the second rotating shaft to the third rotating shaft may be same as a length from the third rotating shaft to the fourth rotating shaft. Also, a rotating angle of the third arm may be twice as a rotating angle of the fourth arm.

In accordance with another embodiment, a substrate transfer apparatus includes a first arm, second arm, third arm, and fourth arm. The first arm may be configured to rotate on a first rotating shaft. The second arm may be configured to rotate on a second rotating shaft disposed at the first arm. The third arm may be configured to rotate on a third rotating shaft disposed at the second arm. The fourth arm may be configured to rotate along with rotation of the third arm, and to rotate on a fourth rotating shaft disposed at the third arm.

The substrate transfer apparatus may perform a rotating operation, a forward/backward operation and a mobile operation. The rotating operation may be configured to rotate on the first rotating shaft. The forward/backward operation may be configured to move the fourth arm in a first direction. The mobile operation may be configured to move the fourth arm in a second direction that is perpendicular to the first direction.

When the mobile operation is provided so as to maintain a direction in which the fourth arm is headed, the first arm, the second arm, the third arm, and the fourth arm may rotate, so that the fourth arm moves in the second direction while rotating. When the forward/backward operation is provided, the first arm may be fixed, and the second arm, the third arm and the fourth arm may rotate, so that the fourth arm moves in the first direction.

In accordance with another embodiment, a substrate transfer apparatus includes a first arm to rotate on a first shaft, a first driver to rotate the first arm, a second arm to rotate on a second shaft coupled to the first arm, a second driver to rotate the second arm, a third arm to rotate on a third shaft coupled to the second arm, a third driver to rotate the third arm, and a fourth arm to rotate with rotation of the third arm and to rotate on a fourth shaft coupled to the third arm. The fourth arm may rotate based on a driving force applied by the third driver.

The apparatus further includes a power conveyor to deliver a driving force of the third driver to the fourth arm. The power conveyor may include a first pulley to rotate based on the driving force of the third driver, a second pulley to rotate the fourth arm, and a belt coupled to the first pulley and second pulley. Another arrangement contemplates a belt without one or both of the pulleys. The apparatus further includes a hand coupled to the fourth arm to hold a substrate.

The substrate transfer apparatus may perform a rotating operation based on rotation of the first shaft, a forward/backward operation to move the hand coupled to the fourth arm in a first direction, and a mobile operation to move the hand in a second direction different from the first direction. The first and second directions may be in a same plane.

The mobile operation may be performed based on rotation of the first arm, second arm, third arm, and fourth arm. Also, the first arm, second arm, third arm, and fourth arm may rotate simultaneously during the mobile operation. Also, the first arm and third arm may rotate in one of a clockwise direction or counterclockwise direction and the second arm and fourth arm may rotate in the other one of the clockwise direction or counterclockwise direction during the mobile operation.

The forward/backward operation may be performed based on rotation of the second arm, third arm, and fourth arm. Also, a first length from the second shaft to the third shaft may be substantially equal to a second length from the third shaft to the fourth shaft.

Also, the third arm may rotate at a first angle during an operation and the fourth arm may rotate at a second angle during the operation, where the first angle is a multiple of the second angle. The operation may be one of rotating operation, a forward/backward operation, or a mobile operation.

Also, the second arm and third arm may rotate and the fourth arm may not rotate during an operation, and the fourth arm maintains a same orientation relative to an axis based on rotation of the second and third arms and the fourth arm not rotating during the operation.

Also, the first arm, second arm, third arm, and fourth arm may rotate independently from one another during at least one operation.

In accordance with another embodiment, a substrate transfer apparatus comprises a first arm configured to rotate on a first shaft, a second arm configured to rotate on a second shaft coupled to the first arm, a third arm configured to rotate on a third shaft coupled to the second arm, and a fourth arm configured to rotate with rotation of the third arm and to rotate on a fourth shaft coupled to the third arm. A number of the first, second, third, and fourth arms cooperate to perform a rotating operation based on rotation on the first shaft, a forward/backward operation to move the fourth arm in a first direction, and a mobile operation to move the fourth arm in a second direction different from the first direction.

The first arm, second arm, third arm, and fourth arm may rotate during the mobile operation, the fourth arm may move in the second direction while rotating during the mobile operation, and the fourth arm may maintain a same orientation while rotating during the mobile operation.

The first arm may not rotate and the second arm, third arm and fourth arm may rotate during the forward/backward operation to allow the fourth arm to move in the first direction.

The first arm, second arm, third arm, and fourth arm may rotate independently from one another during at least one of the rotating, forward/backward, or mobile operations.

One or more embodiments of the substrate transfer apparatus may therefore have a simple structure capable of moving with multiple degrees of freedom including but not limited to three degrees of freedom. In these or other embodiments, semiconductor substrates that are positioned at various directions may be transferred freely. Even in a case when a relative position of a substrate transfer apparatus with respect to a cassette or a chamber is modified, a transfer of a semiconductor substrate may be possible through a movement of an arm.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 shows one embodiment of a substrate transfer apparatus.

FIG. 2 shows another view of the transfer apparatus.

FIG. 3 shows another view of the transfer apparatus.

FIG. 4 shows another view of the transfer apparatus.

FIGS. 5 to 6 show a forward/backward operation.

FIG. 7 shows a rotating operation.

FIGS. 8 to 9 show a mobile operation.

FIGS. 10 to 13 show another aspect of a mobile operation.

### DETAILED DESCRIPTION OF EXAMPLE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (eg., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

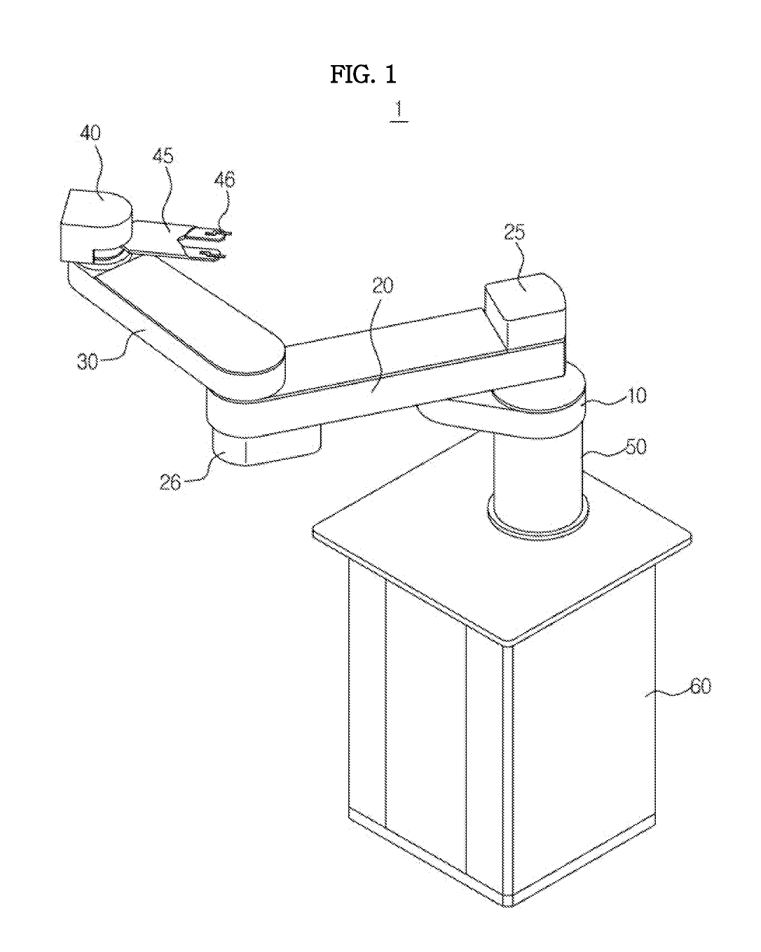

FIG. 1 shows one embodiment of a substrate transfer apparatus which includes a first arm 10, a second arm 20, a third arm 30, and a fourth arm 40. An ascending/descending shaft 50 may be coupled to a lower surface of an end portion of one side of the first arm 10, so that the first arm 10 may ascend and descend. The ascending/descending shaft 50 may be coupled to a body 60.

The arm 10 and the ascending/descending shaft 50 may be separately formed from each other as shown. However, in other embodiments, the first arm 10 and ascending/descending shaft 50 may be integrally formed with each other. In a case when the first arm 10 and the ascending/descending shaft 50 are integrally formed with each other, first arm 10 and ascending/descending shaft 50 may rotate simultaneously.

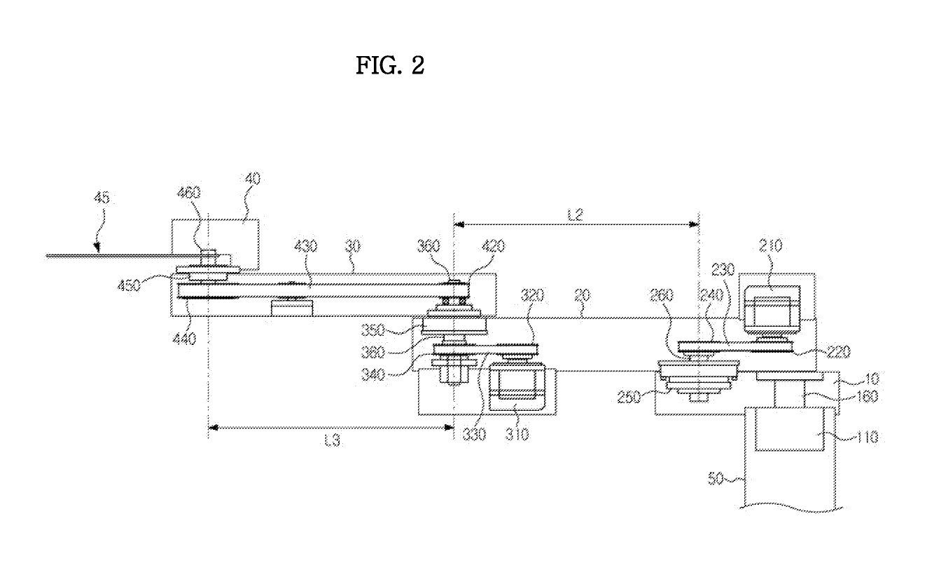

The second arm 20 may be coupled to an end portion of one side of the first arm 10 that is opposite to the one side of the first arm 10 to which the ascending/descending shaft 50 is coupled. A first accommodating unit 25 and a second accommodating unit 26 may be formed at the second arm 20 to accommodate a second driving unit 210 (FIG. 2) and a third driving unit 310 (FIG. 2), both of which will be described later.

The third arm 30 may be coupled to an end portion of second arm 20.

The fourth arm 40 may be coupled to end portion of the third arm 30. The forth arm 40 may be provided with a surface or hand 45 mounted thereto to lift and support a semiconductor substrate. An end portion of the hand 45 may be provided with one or more protrusions, or a finger unit 46, for supporting a semiconductor substrate placed thereon.

The finger unit 46 may be provided with a step having a shape, for example, corresponding to a shape of a semiconductor substrate, so that the semiconductor substrate may be stably placed on the finger unit 46. For example, the semiconductor substrate may have a circular shape, and in this case finger unit 46 may be provided with a step having a shape corresponding to a shape of a portion of the circular shape of the semiconductor substrate formed thereto. In other embodiments, the finger unit may have a shape different from a shape of the semiconductor substrate. Also, the finger unit 46 may be provided with a vacuum suction hole formed thereto so that a semiconductor substrate may be mounted and fixed thereto.

FIG. 2 shows a cross-sectional view of the substrate transfer apparatus of FIG. 1. As shown, ascending/descending shaft 50 may be provided at least partially at an interior thereof with a first driving unit 110 capable of rotating the first arm 10. A first rotating shaft 160 is coupled to the first driving unit 110. The first rotating shaft 160 may serve as a center of rotation of the first arm 10, coupled thereto. As the first driving unit 110 rotates on the first rotating shaft 160, the first arm 10 coupled to the first rotating shaft 160 is rotated.

The first driving unit 110 may also include a motor. The second driving unit 210 and the third driving unit 310 hereinafter may also include a motor. In other embodiments, the driving units 110, 210, and 310 may include other parts to rotate the arms 10, 20, and 30, in addition to or in place of a motor. In a case when the ascending/descending shaft 50 is integrally formed with the first arm 10, the first driving unit 110 may be installed at the body (60 in FIG. 1).

The second driving unit 210 may be disposed at the first accommodating unit 25 of the second arm 20, and the second driving unit 210 is capable of rotating the second arm 20. The second driving unit 210 is coupled to a first belt pulley 220 which rotates by receiving a driving force of the second driving unit 210.

A second pulley 240 is coupled to a second rotating shaft 260 which serves as a center of rotation. A first belt 230 is coupled the first belt pulley 220 and the second belt pulley 240 while surrounding the first belt pulley 220 and the second belt pulley 240. The driving force of the second driving unit 210 is delivered to the second rotating shaft 260 through the first belt pulley 220, the first belt 230, and the second belt pulley 240.

The second rotating shaft 260 is coupled to a first decelerator 250. The first decelerator 250 changes the rotational speed of the first driving unit 110 to a proper speed, so that the second arm 20 is rotated. The second arm 20 and the second driving unit 210 may be connected to each other through the first belt 230. However, in other embodiments, the second driving unit 210 may be directly connected to the second arm 20.

The third driving unit 310 is disposed at the second accommodating unit 26 of the second arm 20, and the third driving unit 310 is capable of generating a driving force to rotate the third arm 30. A third belt pulley 320 is coupled to the third driving unit 310, and the third belt pulley 320 rotates by receiving a driving force of the third driving unit 310.

A fourth belt pulley 340 is coupled to a third rotating shaft 360, which may serve as a center of rotation of the third arm 30. A second belt 330 is coupled to the third belt pulley 320 and the fourth belt pulley 340 while surrounding the third belt pulley 320 and the fourth belt pulley 340. Thus, the fourth belt pulley 340 rotates along with the third belt pulley 320.

The third rotating shaft 360 is coupled to a second decelerator 350, which changes the rotational speed of the second driving unit 210 to a speed so that the third arm 30 is rotated.

A fifth belt pulley 420 is coupled to the second decelerator 350.

A sixth belt pulley 440 is coupled to a fourth rotating shaft 460, which may serve as a center of rotation of the fourth arm 40. A third belt 430 is coupled to the fifth belt pulley 420 and the sixth belt pulley 440 while surrounding the fifth belt pulley 420 and the sixth belt pulley 440. Thus, the sixth belt pulley 440 rotates along with the fifth belt pulley 420.

The third decelerator 450 is coupled to the fifth belt pulley 420 to change the rotational speed delivered from the fifth belt pulley 420 to a speed so that the fourth arm 40 is rotated. That is, the driving force of the third driving unit 310 may be initially delivered to the third arm 30 through the third belt pulley 320, the second belt 330, and the fourth belt pulley 340. The driving force delivered as such is then delivered to the fourth arm 40 through the fifth belt pulley 420, the third belt 430, and the sixth belt pulley 440.

In one embodiment, the fourth arm 40 may not be independently rotated but may be configured to rotate along with the third arm 30. In other embodiments, the fourth arm may be configured to independently rotate. Also, the third driving unit 310 may be directly connected to the third arm 30.

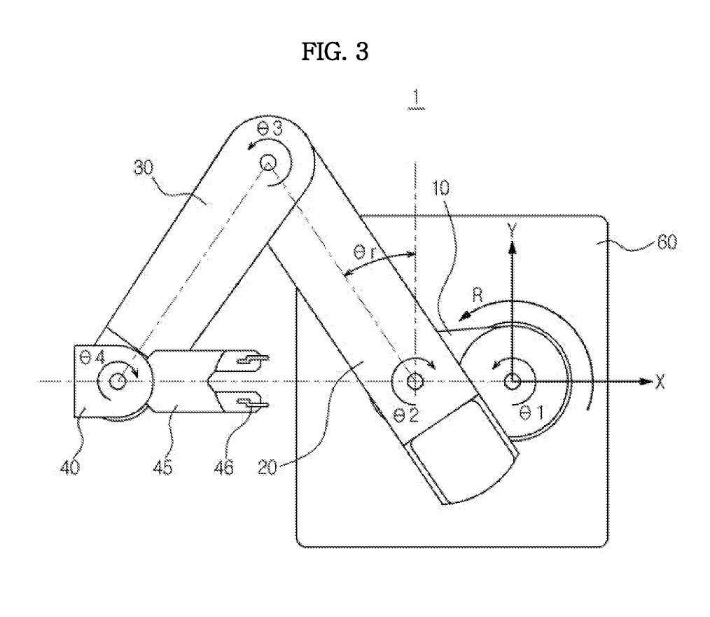

FIG. 3 shows another view of the substrate transfer apparatus of FIG. 1 as seen from above. As illustrated on FIG. 3, the substrate transfer apparatus 1 is free to move in three directions. The substrate transfer apparatus may move in a direction to which hand 45, which is protruded from the fourth arm 40, is headed; that is, an X-direction along a X axis, a Y-direction along a Y shaft perpendicular to the X-axis, and an R-direction to which all of arms 10, 20, 30, and 40 are rotating.

Movement that follows the X axis may be referred to as the forward/backward operation, movement that follows the Y shaft may be referred to as a mobile operation, and the operation along the R direction may be referred to as a rotating operation.

In accordance with one embodiment, rotation of the first arm 10 and third arm 30 in counterclockwise direction may be considered as a reference for defining angles for these arms, while rotation of the second arm 20 and fourth arm 40 in a clockwise direction may be considered as a reference for defining angles for these arms. While these rotational directions are taken as a reference, it is understood that each of arms 10, 20, 30, and 40 may rotate in clockwise and counterclockwise directions.

The rotating angle of the first arm 10 may be given as θ₁, the rotating angle of the second arm 20 may be given as θ₂, the rotating angle of the third arm 30 may be given as θ₃, and the rotating angle of the fourth arm 40 may be given as θ₄. The angle formed by the second arm 20 and the Y axis at a standard posture may be given as θr.

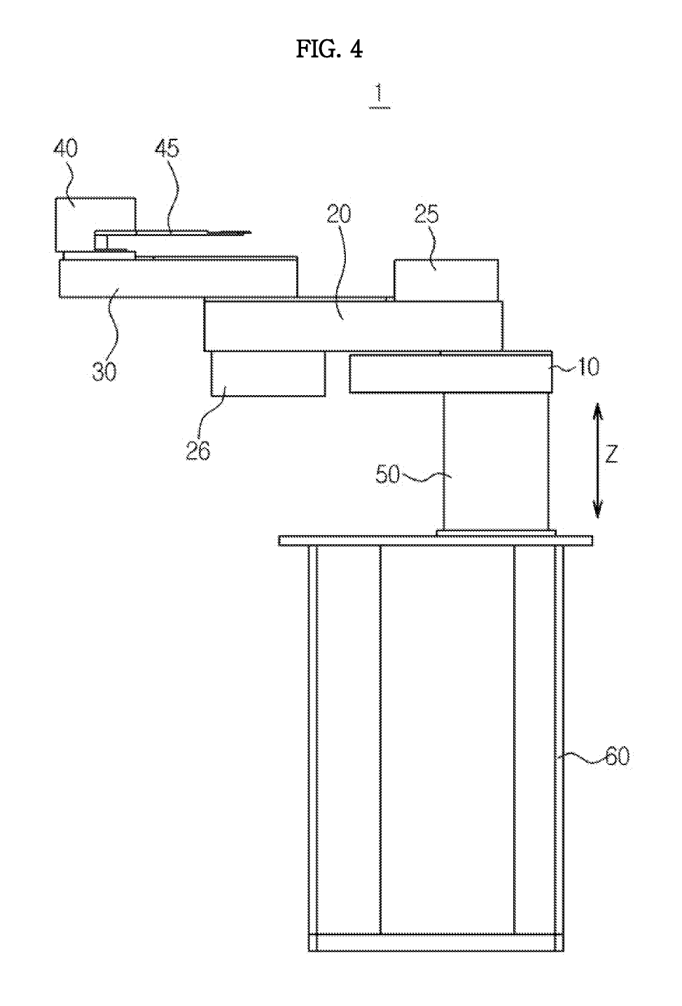

FIG. 4 shows another (front) view of the substrate transfer apparatus of FIG. 1. In this view, one or more or even all of arms 10, 20, 30, and 40 may move vertically. The movement may be independent of one another. In another embodiment, movement of the arms in the Z-axis direction may be accomplished only by ascending/descending of the ascending/descending shaft 50. In this latter embodiment, movement of the arms in the Z direction may be performed by a driving unit of ascending/descending shaft 50. This driving unit may be entirely or partially provided within an interior portion of body 60.

Also, movement in the Z direction may be performed concurrently with or separately from the movements of arms 10, 20, 30, and 40. The movement following the Z shaft may be referred to as an ascending/descending operation.

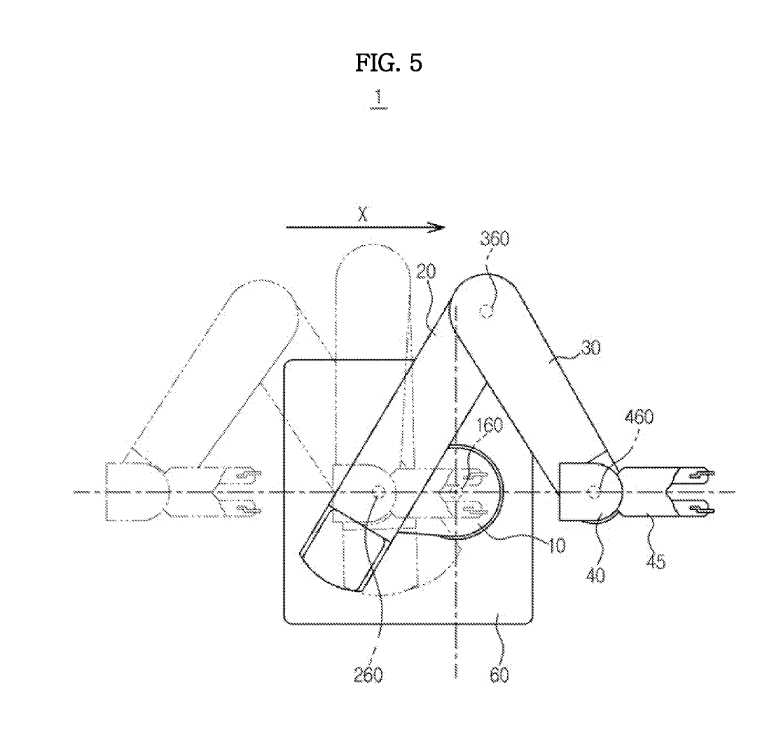

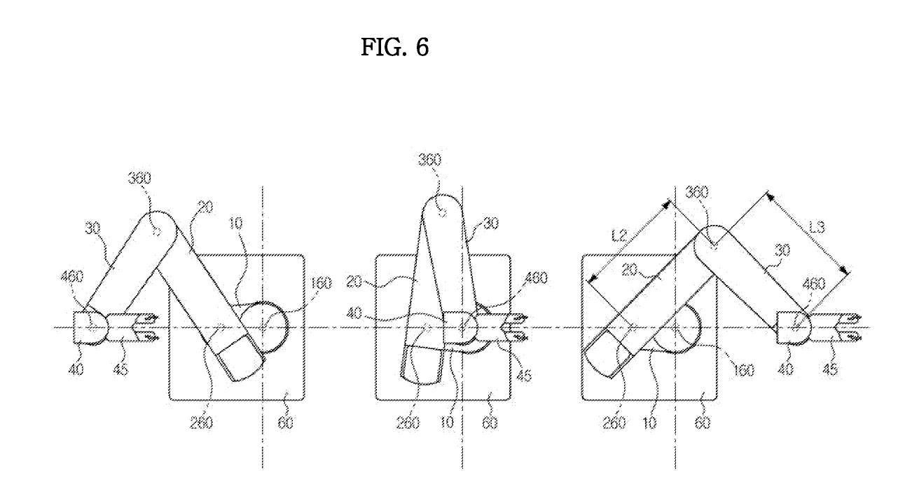

FIGS. 5 to 6 show an example of a forward/backward operation of the substrate transfer apparatus of FIG. 1. A forward/backward operation may be understood to movement of hand 45 (mounted to fourth arm 40) along the X axis while hand 45. This movement may be performed while hand 45 maintains a same orientation (or angle) relative to a reference point such as the X axis and/or one or more other points such as, for example, a point on shaft 50 or body 60.

In FIGS. 5 and 6, hand 45 is shown to move forward while maintaining an orientation parallel to the X axis. As hand 45 moves forward/backward along this axis, the hand performs a motion to pull out a semiconductor substrate at an inside a chamber or to insert a semiconductor substrate into an inside a chamber.

In accordance with one embodiment, when hand 45 performs the forward/backward operation, first arm 10 may not be rotated but may be stationary. However, the second arm 20, third arm 30, and fourth arm 40 may be rotated during this operation.

In order for hand 45 to move along the X axis while maintaining a same orientation, arms 20, 30, and 40 may rotate at corresponding rotating angles. To allow for this movement, a length of the second arm 20 and a length of the third arm 30 may be adjusted.

More particularly, for second arm 20, the length from the second rotating shaft 260 to the third rotating shaft 360 is defined as L2. And, for the third arm 30, the length from the third rotating shaft 360 to the fourth rotating shaft 460 may be defined as L3. In one embodiment, lengths L2 and L3 may be about same.

During a forward/backward operation, if the lengths of L2 and L3 are adjusted by about the same amount, the ratio of rotating angles θ₂, θ₃, and θ₄ of the arms may be 1:2:1. On FIG. 3, θ₂ and the θ₄ are the angles that the second arm 20 and fourth arm 40 rotate in the clockwise direction, while the θ₃ is the angle that third arm 30 rotates in the counterclockwise direction.

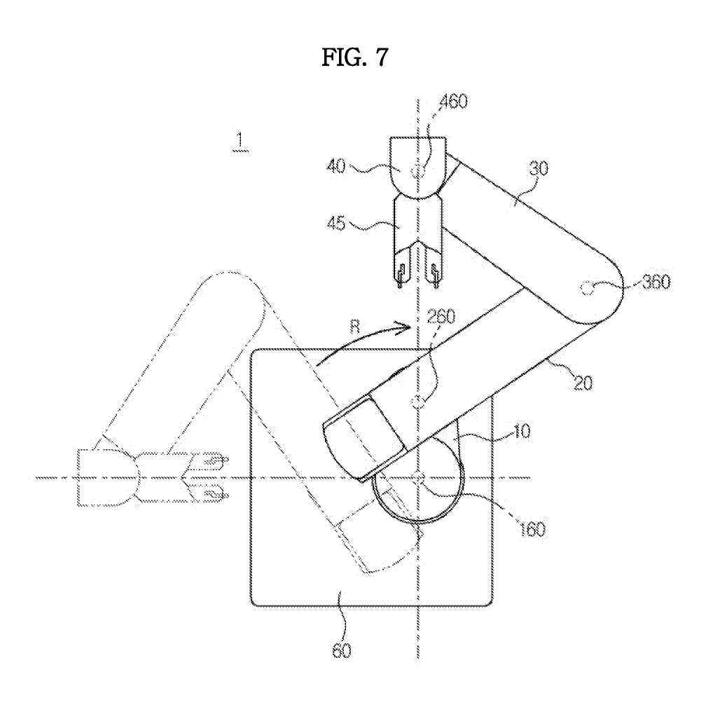

FIG. 7 shows a rotating operation of the substrate transfer apparatus of FIG. 1. As illustrated on FIG. 7, all of arms 10, 20, 30, and 40 rotate and the motions of these arms may be said correspond to a rotating operation. In this rotating operation, the direction to which the hand 45 is headed may be changed as desired.

In this rotating operation, all the arms move but this movement is accomplished only by rotation of the first arm 10. The other arms may remain fixed in terms of their rotation so as to maintain a same orientation.

The rotating operation may be performed to allow hand 45 to move reciprocally in a direction toward a cassette or a chamber, which may be oriented in different directions. That is, before performing the forward/backward operation, the rotating operation may be performed to allow hand 45 to move toward in a desired direction. After the rotating operation, the forward/backward operation or the mobile operation may be performed.

In accordance with one embodiment, the ascending/descending operation may be concurrently performed with the rotating operation. The rotating angle of the rotating operation may be determined, for example, according to the degree of the rotation of the first arm 10.

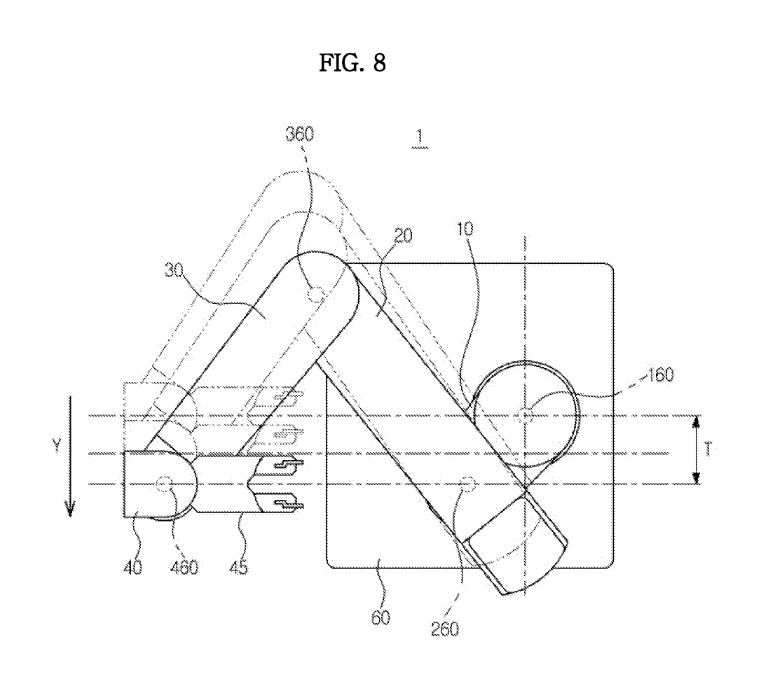

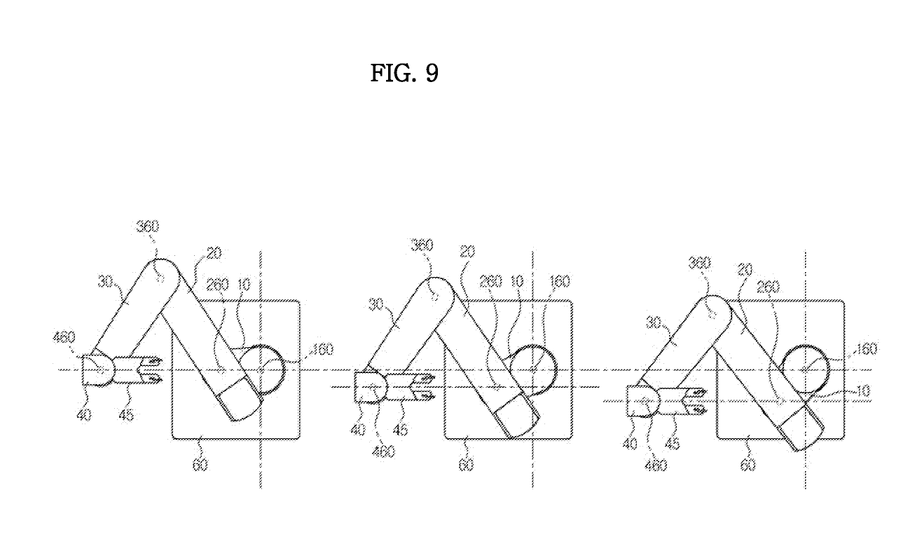

FIGS. 8 to 9 show one type of mobile operation of the substrate transfer apparatus of FIG. 1. The mobile operation may be understood to correspond to motion of hand 45 (mounted at fourth arm 40) along the Y axis while maintaining a same orientation.

In this mobile operation, hand 45 moves in the Y-axis direction while the finger unit 46 of the hand 45 maintains the posture of heading toward the X direction. The mobile operation may be performed to determine or set a position of hand 45 before and/or after the hand moves back and forth between the chamber and cassette that are disposed in line with each other.

In order to perform movement along the Y axis, the first arm 10 and third arm 30 may rotate counterclockwise and second arm 20 and fourth arm 40 may rotate clockwise. In order to perform a movement opposite to that shown in FIGS. 8 and 9, first arm 10 and third arm 30 may rotate clockwise and second arm 20 and fourth arm 40 may rotate counterclockwise.

In accordance with one embodiment, to optimize or otherwise to achieve a desired transfer path of a semiconductor substrate and rotating angle(s) of the arms 10, 20, 30, and 40, a length of the second arm 20 and a length of the third arm 30 may be adjusted and L2 (FIG. 6) and L3 (FIG. 6) may be about same.

In a case where L2 and L3 are adjusted to be about the same, each of the rotating angles may be determined according to the following formulas.

When the distance of movement of hand 45 is given by T, the lengths of arms 10, 20, and 30 are given by L1, L2 and L3 respectively, and the rotating angles of arms 10, 20, 30, and 40 are given by θ₁, θ₂, θ₃, and θ₄ respectively, and the angle of second arm 20 is given by θr, the rotating angles may be determined by using the following formulas.

θ₁=arc sin (T/L2)

θ₂=θ₁+[θr−arc sin {2·L2·sin θr−L1(1−cos θ₁)}]

θ₃=2*[θr−arc sin {2·L2·sin θr−L1 (1−cos θ₁)}]

θ₄=θr−arc sin {2·L2·sin θr−L1 (1−cos θ₁)}

By reviewing the above formulas, in accordance with one embodiment, the rotating angle θ₃ of the third arm 30 may be twice of the rotating angle θ₄ of the fourth arm 40. That is, in order for the rotating angle of the fourth arm 40 to be a half the rotating angle of the third arm 30, the third decelerator 450 (FIG. 2) may be adjusted.

While the above formulas may allow hand 45 to move along the Y-axis direction while maintaining the same orientation, in other embodiments the rotating angles of arms 10, 20, 30, and 40 may be different and still allow hand 45 to maintain the same orientation while moving along the Y-axis.

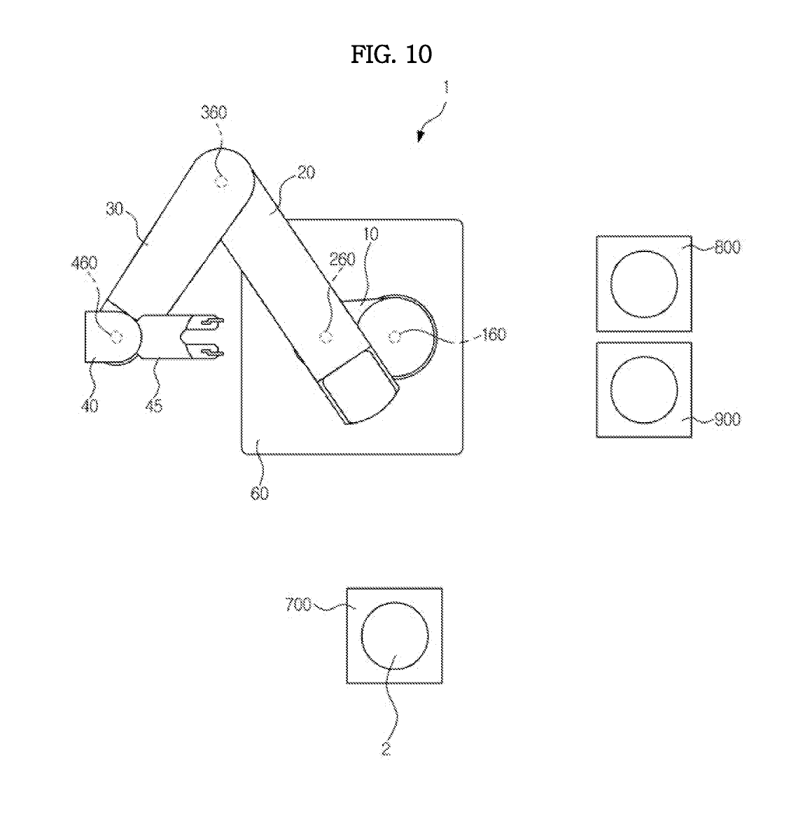

FIGS. 10 to 13 show an example of motion of the substrate transfer apparatus of FIG. 1. FIG. 10 shows one arrangement in which cassette 700 and chambers 800 and 900 are disposed around the substrate transfer apparatus 1. In other arrangements, the position of cassette 700 and chambers 800 and 900 may be disposed differently along with each of the apparatuses.

Using the substrate transfer apparatus as a reference, the first chamber 800 and second chamber 900 may be located in line with each other in the same direction. Alternatively, two portions on which a semiconductor substrate may be placed may be formed on a single chamber. The substrate transfer apparatus 1 may move using the orientation in FIG. 10 as a starting point.

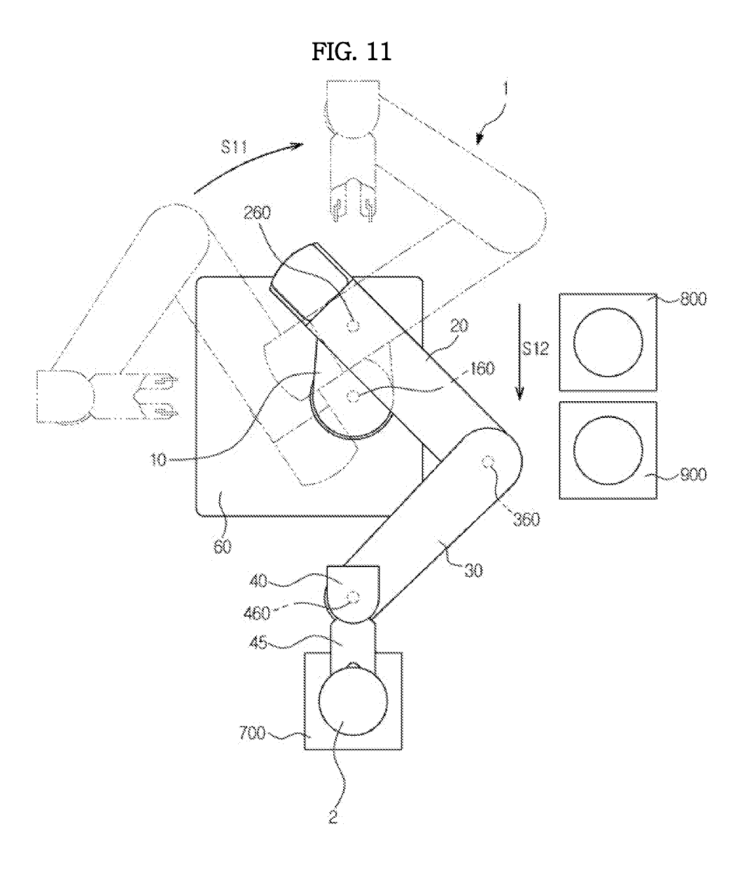

FIGS. 11 to 13 show various motions of the substrate transfer apparatus 1 using the orientation in FIG. 10 as a reference. In other embodiments, a different arrangement may be used as a reference.

FIG. 11 shows a motion to pull out a semiconductor substrate from a cassette having semiconductor substrates therein. As illustrated on FIG. 11, cassette 700 is at a position that points in a direction different from the direction in which hand 45 is pointing in the reference position, in FIG. 10.

Then, hand 45 performs a motion to move toward the cassette 700. This motion involves performing a rotating operation S11. The rotating operation may correspond to a motion where only first arm 10 rotates on the first rotating shaft 160. By having the first arm 10 rotated in a proper angle, hand 45 changes its orientation relative to cassette 700, e.g., points towards the cassette.

Next, a forward/backward operation is performed (S12) to advance hand 45 toward cassette 700 after the rotating operation is performed. The forward/backward operation, as previously indicated, may correspond to a motion in which first arm 10 is fixed while second arm 20, third arm 30, and fourth arm 40 are rotated.

To achieve an optimal or otherwise desired transfer path of a semiconductor substrate and a rotating angle of each of arms 10, 20, 30, and 40, a length of the second arm 20 and a length of the third arm 30 may be adjusted and L2 (FIG. 6) and L3 (FIG. 6) may be about same. If the lengths of the L2 and the L3 are adjusted to be or are at about same, rotating angles θ₂, θ₃, and θ₄ may correspond to the ratio of 1:2:1, as previously explained.

When hand 45 is moved to a position adjacent the cassette, a semiconductor substrate 2 is placed on the finger unit 46 of the hand 45. As the semiconductor substrate 2 is placed on the finger unit 46, the substrate transfer apparatus 1 may be able to return to the orientation shown in FIG. 10 by performing movements and rotations in a reverse manner. That is, by performing the forward/backward operation of second step (S22) and performing the rotating operation of first step (S11), the substrate transfer apparatus 1 may be able to return to a standard posture or orientation as shown in FIG. 10.

After returning to the standard posture while having the semiconductor substrate 2 placed thereon, the substrate transfer apparatus 1 may be able to perform a motion to transfer a semiconductor substrate to the chambers 800 and 900.

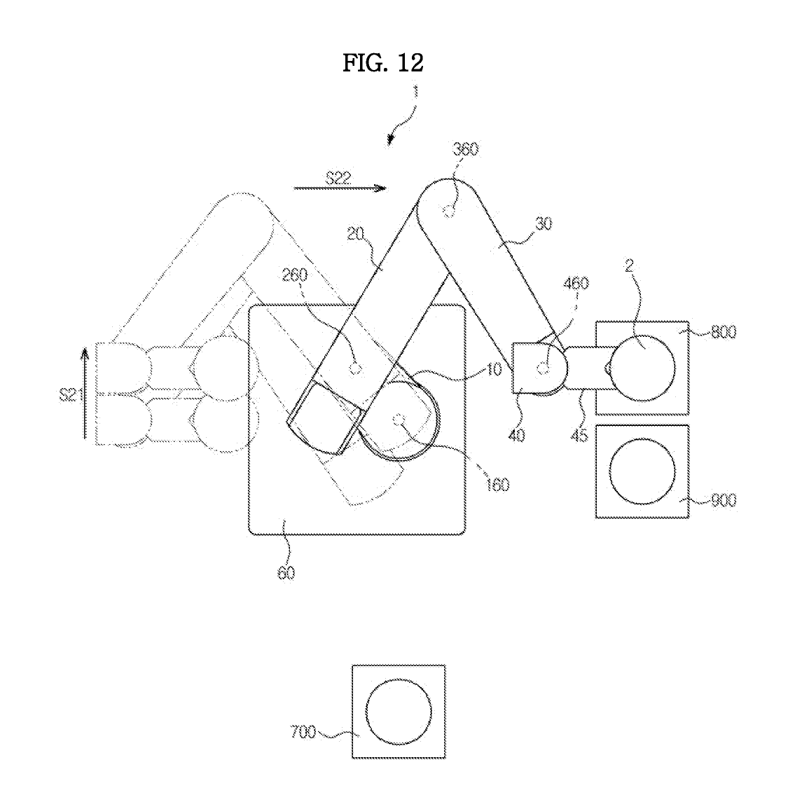

FIG. 12 shows a motion of transferring a semiconductor substrate to the first chamber. As illustrated on FIG. 12, in the standard posture (FIG. 10), the first chamber 800 is disposed in the X direction of the hand 45, but the position of the first chamber 800 is not on the same Y axis as the hand 45. Thus, a motion is performed (S21) to have the hand 45 positioned in line with the first chamber 800, and then, a motion is performed to have the hand 45 to move toward the first chamber 800.

These motions involve motions S21 and S22 that correspond to a mobile operation. As previously mentioned, this mobile operation involves motion where all of arms 10, 20, 30, and 40 rotate. Through the mobile operation, the hand 45 is moved by following the Y axis, and thus the hand 45 may be positioned in line with the first chamber 800.

If length L2 (FIG. 2) and length L3 (FIG. 2) are made to be about the same by adjusting the lengths of second arm 20 and third arm 30, the rotating angle θ₃ of the third arm 30 may be twice as the rotating angle θ₄ of the fourth arm 40. As hand 45 moves in an opposite direction of the mobile operation that is illustrated earlier on FIG. 8, the first arm 10 and the third arm 30 may rotate in clockwise direction while the second arm 20 and the fourth arm 40 may rotate in counterclockwise direction.

After motion S21, a forward/backward operation S22 is performed. This motion involves movement towards first chamber 800; that is, a forward/backward operation involves motion where a position of first arm 10 is fixed while second arm 20, third arm 30, and fourth arm 40 are rotated.

When hand 45 reaches a position adjacent first chamber 800, the semiconductor substrate 2 that is placed on the finger unit 46 of the hand 45 may be mounted on the first chamber 800. As the semiconductor substrate 2 is placed on the first chamber 800, the substrate transfer apparatus 1 may be able to return to the standard posture (FIG. 10) by performing the previous movements in a reverse manner. That is, by performing the forward/backward operation S22 and then by performing mobile operation S11.

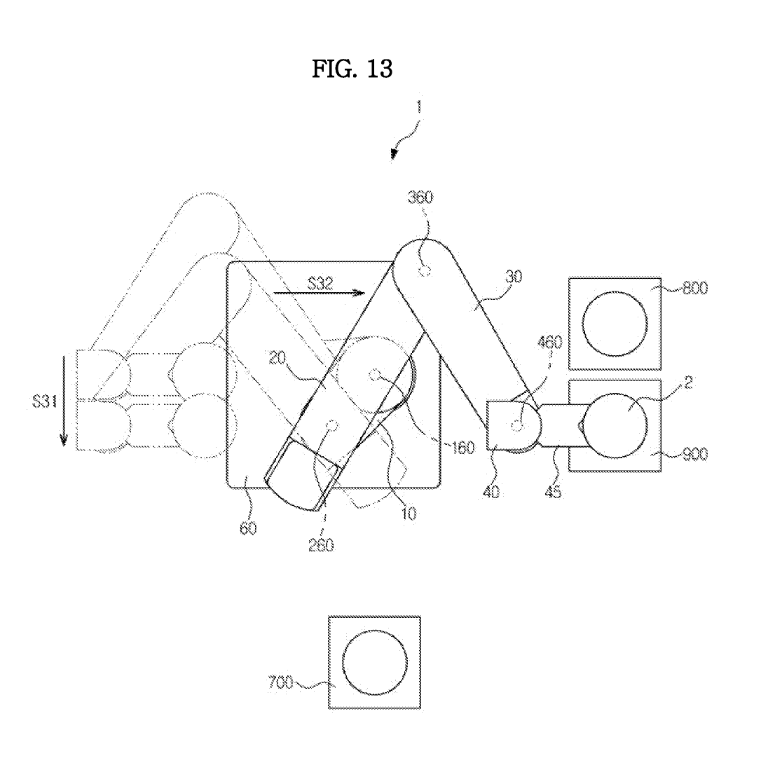

FIG. 13 shows a motion of transferring a semiconductor substrate to the second chamber. As illustrated on FIG. 13, at the standard posture (FIG. 10), the first chamber 800 is disposed in the X-axis direction of the hand 45, but the position of the first chamber is not on the same Y axis as the hand 45. Thus, a motion (S31) is performed to have the hand 45 positioned in line with the second chamber 900. Then, a motion (S32) is performed to have the hand 45 to move toward the second chamber 900.

The first motion S31 may be referred to as a mobile operation. Different from FIG. 12, this type of mobile operation involvement movement in the same direction as that of the mobile operation in FIG. 8. Thus, the first arm 10 and the third arm 30 rotate in counterclockwise direction, while the second arm 20 and the fourth arm 40 rotate in clockwise direction.

As the mobile operation is completed, the forward/backward operation S32 is performed. By the forward/backward operation, hand 45 is moved toward the second chamber 900. When hand 45 is at a position adjacent the second chamber 800, the semiconductor substrate 2 that is placed on the finger unit 46 of the hand 45 is mounted on the second chamber 900. After the semiconductor substrate 2 is mounted on the second chamber 900, the substrate transfer apparatus 1 may be able to return to the standard posture.

Prior to performing the motion illustrated on FIG. 13 and in a case when the semiconductor substrate 2 is not present at the hand 45, the motion to pull out the semiconductor substrate 2 from the cassette 700 may be performed first by performing the motion that is illustrated on FIG. 11.

The orientation, rotating angles and movements of the arms of the substrate transfer apparatus 1, the position of cassette 700, and the positions of chambers 800 and 900 illustrated in FIGS. 11 to 13 are examples. In other embodiments, the positions, movements, or rotating angles may be different.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A substrate transfer apparatus, comprising:
a first arm configured to rotate on a first shaft;
a first driver configured to rotate the first arm;
a second arm configured to rotate on a second shaft coupled to the first arm;
a second driver configured to rotate the second arm;
a third arm configured to rotate on a third shaft coupled to the second arm;
a third driver configured to rotate the third arm; and
a fourth arm configured to rotate with rotation of the third arm and to rotate on a fourth shaft coupled to the third arm.

2. The substrate transfer apparatus of claim 1, wherein the fourth arm is configured to rotate based on a driving force applied by the third driver.

3. The substrate transfer apparatus of claim 1, further comprising:
a power conveyor configured to deliver a driving force of the third driver to the fourth arm.

4. The substrate transfer apparatus of claim 3, wherein the power conveyor includes a belt.

5. The substrate transfer apparatus of claim 4, wherein the power conveyor includes a first pulley configured to be rotated by the driving force of the third driver, and a second pulley configured to rotate the fourth arm, and the belt is coupled to the first pulley and second pulley.

6. The substrate transfer apparatus of claim 1, further comprising:
a hand coupled to the fourth arm to hold a substrate.

7. The substrate transfer apparatus of claim 6, wherein the substrate transfer apparatus performs:
a rotating operation based on rotation of the first shaft;
a forward/backward operation to move the hand coupled to the fourth arm in a first direction; and
a mobile operation to move the hand in a second direction different from the first direction, the first and second directions in a same plane.

8. The substrate transfer apparatus of claim 7, wherein the mobile operation is performed based on rotation of the first arm, second arm, third arm, and fourth arm.

9. The substrate transfer apparatus of claim 8, wherein the first arm, second arm, third arm, and fourth arm rotate simultaneously during the mobile operation.

10. The substrate transfer apparatus of claim 7, wherein the first arm and third arm rotate in one of a clockwise direction or counterclockwise direction, and the second arm and the fourth arm rotate in the other one of the clockwise direction or counterclockwise direction during the mobile operation.

11. The substrate transfer apparatus of claim 7, wherein the forward/backward operation is performed based on rotation of the second arm, third arm, and fourth arm.

12. The substrate transfer apparatus of claim 1, wherein a first length from the second shaft to the third shaft is substantially equal to a second length from the third shaft to the fourth shaft.

13. The substrate transfer apparatus of claim 1, wherein:
the third arm rotates at a first angle during an operation,
the fourth arm rotates at a second angle during the operation, and
the first angle is a multiple of the second angle.

14. The substrate transfer apparatus of claim 13, wherein the operation is one of rotating operation, a forward/backward operation, or a mobile operation.

15. The substrate transfer apparatus of claim 13, wherein
the second arm and third arm rotate and the fourth arm does not rotate during an operation, and
the fourth arm maintains a same orientation relative to an axis based on rotation of the second and third arms and the fourth arm not rotating during the operation.

16. The substrate transfer apparatus of claim 1, wherein the first arm, second arm, third arm, and fourth arm rotate independently from one another during at least one operation.

17. A substrate transfer apparatus, comprising:
a first arm configured to rotate on a first shaft;
a second arm configured to rotate on a second shaft coupled to the first arm;
a third arm configured to rotate on a third shaft coupled to the second arm; and
a fourth arm configured to rotate with rotation of the third arm and to rotate on a fourth shaft coupled to the third arm, a number of the first, second, third, and fourth arms cooperating to perform
a rotating operation based on rotation on the first shaft;
a forward/backward operation to move the fourth arm in a first direction; and
a mobile operation to move the fourth arm in a second direction different from the first direction.

18. The substrate transfer apparatus of claim 17, wherein
the first arm, second arm, third arm, and fourth arm rotate during the mobile operation, the fourth arm moving in the second direction while rotating during the mobile operation, the fourth arm maintaining a same orientation while rotating during the mobile operation.

19. The substrate transfer apparatus of claim 17, wherein the first arm does not rotate and the second arm, third arm and fourth arm rotate during the forward/backward operation to allow the fourth arm to move in the first direction.

20. The substrate transfer apparatus of claim 17 wherein the first arm, second arm, third arm, and fourth arm rotate independently from one another during at least one of the rotating, forward/backward, or mobile operations.
